(19) United States
(12) Patent Application Publication
(10) Pub. No.: US 2026/0237955 A1
(43) Pub. Date: Aug. 13, 2026

(54) METHOD AND SYSTEM TO STABILIZE A FREQUENCY SUM GENERATED LASER

(71) Applicant: ASML Netherlands B.V., Veldhoven (NL)

(72) Inventors: Maarten Jozef JANSEN, Hoogeloon (NL); Eduard Martinus KLARENBEEK, Soerendonk (NL); Manoj Kumar MRIDHA, Eindhoven (NL); Ping LIU, Eindhoven (NL)

(73) Assignee: ASML Netherlands B.V., Veldhoven (NL)

(21) Appl. No.: 19/156,835

(22) PCT Filed: Feb. 16, 2024
(86) PCT No.: PCT/EP2024/054009

§ 371 Date: Aug. 14, 2025

(30) Foreign Application Priority Data
Mar. 3, 2023 (EP) 23159806.1

(51) Int. Cl. H01S 3/00; G03F 7/00; H01S 3/13; H01S 3/137; H01S 3/23

(52) U.S. Cl. CPC H01S 3/0092; G03F 7/70025; H01S 3/1303; H01S 3/1304; H01S 3/1305; H01S 3/137; H01S 3/2391

(57) ABSTRACT

The disclosure provides a method of operating a sum-frequency laser, comprising the steps of simultaneously emitting a first light beam having a first frequency from a first light source and a second light beam having a second frequency from a second light source; modulating the first frequency in a first direction and modulating the second frequency in opposite direction and with matched tuning frequencies; and sending the first and second light beams to a summing device and outputting a stabilized sum-frequency light beam from the summing device.

### CROSS-REFERENCE TO RELATED APPLICATIONS

The application claims priority of EP Application Serial No. 23159806.1 which was filed on 3 Mar. 2023 and which is incorporated herein in its entirety by reference.

### FIELD

The present invention relates to a method and system to stabilize a sum-frequency generated (SFG) laser. A SFG laser may be used in, for example, metrology systems. State of the art metrology systems can be used to, for instance, measure displacement of parts of a lithographic apparatus, including parts of projection systems for optical lithography systems.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask) onto a layer of radiation-sensitive material (resist) provided on a substrate (e.g., a wafer).

As semiconductor manufacturing processes continue to advance, the dimensions of circuit elements have continually been reduced while the amount of functional elements, such as transistors, per device has been steadily increasing over decades, following a trend commonly referred to as ‘Moore's law’. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm. A lithographic apparatus, which uses extreme ultraviolet (EUV) radiation, having a wavelength within a range of 4 nm to 20 nm, for example 6.7 nm or 13.5 nm, may be used to form smaller features on a substrate than a lithographic apparatus which uses, for example, radiation with a wavelength of 193 nm.

A sum-frequency generated (SFG) laser is a laser having an output beam with a frequency equal to the sum of two mixed input laser beams. Each input laser may have a cavity wherein laser light of a particular frequency can be generated. The laser frequency of one or both lasers may be adjusted, for instance by modification of thermal control, by current control, by piezo-actuators, or by a grating element. The output of a SFG laser should be stabilized to provide a sum-frequency output free of modulation, required for accuracy of applications. Known approaches for stabilizing the output of a SFG laser include locking the total sum-frequency output to a reference, e.g. a gas absorption peak, or a reference laser with a frequency offset.

Mode hopping is a phenomenon whereby a laser exhibits sudden jumps of optical frequency, which is associated with transitions between different modes of its resonator. Existing methods of laser frequency adjustment involve a regular re-calibration of thermal and piezo setpoint to find a “safe zone” where no sidebands (sidemodes) occur, to avoid mode hopping. However, even the occurrence of additional eigenfrequencies or additional wavelengths in the cavity of the laser may lead to instabilities in the output of the SFG laser. Even when such instabilities are only temporary, they need to be avoided for continuous and high-end applications, such as in lithographic machines.

Sidemodes can be detected by observing the presence of the free spectral range frequency in the optical output of the laser. The presence of sidemodes can be avoided by choosing an appropriate thermal and piezo setpoint.

During calibration of the laser using existing methods, the center-frequency of the SFG laser may vary. Consequently, the operational point of the laser may approach a situation where a side mode emerges. A separate calibration per laser will impact the SFG frequency stability and throughput loss as a result of this. Also, drift of the input laser frequencies is still possible during operation, despite various measures and control systems to keep each input laser within a narrow range from a setpoint. As such, the output may be inherently unstable.

CN101303507A discloses an SFG laser whereby it is desired to change the frequency of a first input light beams while keeping the wavelength of the sum light beam constant. This is achieved by changing the frequency of a second input light beam.

EP1650597A1 discloses an SFG laser and a number of possible combinations of the frequencies of the input light beams while keeping the frequency of the sum output light beam constant.

The systems as described above may all involve temporary instabilities in the SFG laser output. It is an aim of the present disclosure to provide a stabilized sum frequency generated laser.

### SUMMARY

The disclosure provides a method of operating a sum-frequency laser, comprising the steps of:
simultaneously emitting a first light beam having a first frequency from a first light source and a second light beam having a second frequency from a second light source;
modulating the first frequency in a first direction and modulating the second frequency in opposite direction and with matched tuning frequencies; and
sending the first and second light beams to a summing device and outputting a stabilized sum-frequency light beam from the summing device.

In an embodiment, the method comprises the steps of:
detecting a sidemode in one of the first light beam and the second light beam; and
reversing the modulation direction of the first frequency and the second frequency if the detected sidemode exceeds a predetermined threshold.

In an embodiment, the threshold includes one or more of: an amplitude of the sidemode, power of the sidemode, brightness, or ratio thereof with respect to the same aspect of said first or second frequency.

In an embodiment, the threshold is a ratio of amplitude or power or the sidemode with respect to the power or amplitude of the first frequency or the second frequency.

In an embodiment, the threshold is about 40 dB, being a ratio between power of the main mode and the detected sidemode.

In an embodiment, the frequency change of the first light beam and the frequency change of the second light beam are 180 degrees out of phase.

In an embodiment, the step of detecting a sidemode includes power measurement of the free spectral range frequency content of the first light source and the second light source.

In an embodiment, the step of detecting a side mode includes diverting a part of the first light beam to a first sensor, and diverting a part of the second light beam to a second sensor.

In an embodiment, the first sensor and the second sensor comprise a power detector and an algorithm for providing a signal that correlates to the power of the sidemode.

In an embodiment, modulating the first frequency and modulating the second frequency includes thermal and/or current and/or piezo tuning of respectively the first light source and the second light source.

In an embodiment, the matched tuning frequencies of the step of modulating the first and second light beam are in the mHz to kHz range.

According to another aspect, the disclosure provides an exposure apparatus including one of more sum-frequency generated lasers using a method of operating according to the invention.

According to another aspect, the disclosure provides a lithographic apparatus including one of more sum-frequency generated lasers using a method of operating according to the invention.

According to yet another aspect, the disclosure provides a projection system for an optical lithography system including one of more sum-frequency generated lasers using a method of operating according to the invention.

### BRIEF DESCRIPTION OF THE DRAWINGS

Embodiments of the invention will now be described, by way of example only, with reference to the accompanying schematic drawings, in which:

FIG. 1 depicts a schematic overview of a lithographic apparatus;

FIG. 2 depicts a diagram of an embodiment of a system of the disclosure;

FIGS. 3A and 3B depicts exemplary diagrams of a sidemode power amplitude observed in the laser power output, with wavelength controlling piezo voltage (vertical axis) versus wavelength controlling temperature of the laser cavity (horizontal axis), indicating examples of mode hopping regions;

FIG. 4 depicts an exemplary diagram of laser tuning curves, with the vertical axis exemplifying the laser wavelength of the laser beam and with the horizontal axis exemplifying the laser temperature, indicating examples of laser tuning with a fixed piezo setpoint and prevalence of cavity modes;

FIG. 5 depicts a diagram exemplifying modes of a tuneable laser;

FIG. 6 depicts a diagram of another embodiment of a system of the disclosure;

FIGS. 7A and 7B depict exemplary diagrams of laser control according to a method of the present disclosure, indicating wavelength modulation of respective lasers and resulting sidemode power (vertical axis) versus a controllable parameter such as piezo voltage (horizontal axis); and

FIG. 8 diagrammatically depicts an embodiment of the present disclosure.

### DETAILED DESCRIPTION

In the present document, the terms “radiation” and “beam” are used to encompass all types of electromagnetic radiation. Radiation may include (deep) ultraviolet radiation (e.g. with a wavelength of 365, 248, 193, 157 or 126 nm) and EUV (extreme ultra-violet radiation, e.g. having a wavelength in the range of about 5 to 100 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

A “beam splitter” (also spelled beamsplitter) is an optical device that splits a beam of light in two. It is a part of many optical systems. In a first version, a beam splitter may comprise a cube, made from two triangular glass prisms which are glued together at their base using, for instance, polyester, epoxy, or urethane-based adhesives. The thickness of the adhesive resin layer is adjusted such that (for a certain wavelength) half of the light incident through one “port” (typically a face of the cube) is reflected and the other half is transmitted due to Frustrated Total Internal Reflection (FTIR). Polarizing beam splitters, such as a Wollaston prism, use birefringent materials to split light into two beams of orthogonal polarization states. A second option is the use of a semi-transparent mirror. This is composed of an optical substrate, which is often a sheet of glass or plastic, with a partially transparent thin coating of metal. The thin coating can be aluminium or silver deposited using a physical vapor deposition method. The thickness of the coating is controlled so that a predetermined part (for instance half, but this can be any ratio between 0 and 100%) of the light, which is incident at a 45-degree angle and not absorbed by the coating or substrate material, is transmitted and the remainder is reflected. A third version of the beam splitter is a dichroic mirrored prism assembly which uses dichroic optical coatings to divide an incoming light beam into a number of spectrally distinct output beams.

A “gas reference cell” is a cell filled with some gas, normally used in laser absorption spectroscopy. The absorption coefficient of light in the gas, or some other effect resulting from the interaction of the gas with light, such as frequency-dependent absorption spectrum, allows comparison with a reference beam. Typically, small changes to the light beam caused by the passage through the gas are measured as a function of the optical frequency of the laser beam, and the results are presented in the form of a spectrum, for example, an absorption spectrum. The obtained peaks in such a spectrum can be used to identify certain chemical species and to measure their concentration. For such measurements, one often uses wavelength-tunable single-frequency lasers. Once the spectrum and the chemical composition in the cell is known, the gas cell also allows the opposite process of using the absorption spectrum to identify the frequency or wavelength of the laser light.

A gas reference cell is typically provided with appropriate optical windows (with high transmissivity over the whole relevant spectral region) for the light to enter and leave the cell. Reference gas cells are commercially available with many different gases, including both atomic and (often diatomic) molecular gases. Typical examples are iodine (I₂), hydrogen (H₂), helium, carbon monoxide (CO) and acetylene (C₂H₂). A wide range of standard spectral lines can thus be used. In some cases, alkali metals such as sodium (Na), potassium (K), rubidium (Rb) or cesium (Cs) are used, which develop a sufficiently high vapor pressure at least when electrically heated to some appropriate temperature. Such cells may be called vapor cells. A sealed gas cell should be reliably leak-free. Therefore, helium leak testing is often applied.

An “absorption cell” or “molecular absorption cell” is a device comprising a gas reference cell. The absorption cell can compare the difference between the intensity of two portions of the same beam, one portion sent to the gas reference cell and to a first sensor for receiving the light once it has passed through the reference cell at least once, and a second portion sent unobstructed to a second sensor used as a reference.

“Refractive Index” (Index of Refraction) is a value calculated from the ratio of the speed of light in a vacuum to that in a second medium of greater density. The refractive index variable may be symbolized by the letter n or n′ in descriptive text and mathematical equations.

An “interferometer” or a “laser interferometer” can measure distance or displacement by measuring the phase difference between two light beams, one sent to a first reflector or first surface at a fixed reference distance, and one sent to a second reflector or surface at another distance. When the two reflected signals are recombined in the interferometer, the resulting phase is related to the distance of the second surface from the interferometer. If the distance of the second surface changes, so does the phase of the combined signal. The utility of these methods are that the measurement can be made over long distances while maintaining accuracy.

In a heterodyne interferometer, the measurement beam and reference beam that interfere at a detector are generally originating from the same laser source. The source may have been given a frequency offset to allow for heterodyne phase detection. The two (split) frequencies may however also be generated by two different, frequency-locked or phase-locked lasers.

A “wavelength tracker” is a specific version of an interferometer set up to measure a phase difference between two reflected light beams, one beam reflecting on a first fixed reflector providing a first reference axis and a second beam reflecting on a second fixed reflector providing a second reference axis having a different length than the first axis. As the two reflective surfaces are fixed, the measured phase difference will change only if the wavelength of the light beam changes. Thus, a wavelength tracker allows to monitor deviations of the wavelength from a setpoint.

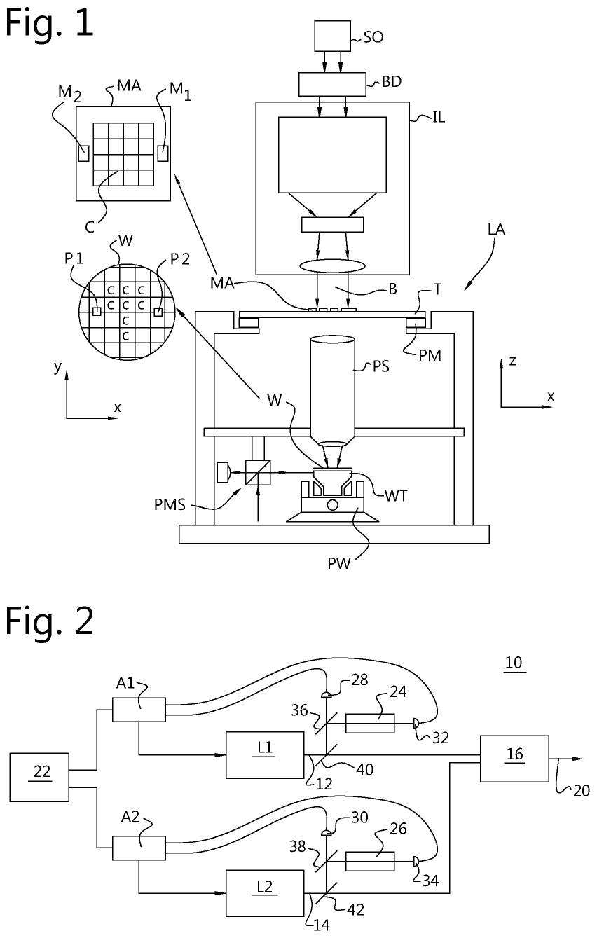

FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W-which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

To clarify the invention, a Cartesian coordinate system is used. The Cartesian coordinate system has three axes, i.e., an x-axis, a y-axis and a z-axis. Each of the three axes is orthogonal to the other two axes. A rotation around the x-axis is referred to as an Rx-rotation. A rotation around the y-axis is referred to as an Ry-rotation. A rotation around about the z-axis is referred to as an Rz-rotation. The x-axis and the y-axis define a horizontal plane, whereas the z-axis is in a vertical direction. The Cartesian coordinate system is not limiting the invention and is used for clarification only. Instead, another coordinate system, such as a cylindrical coordinate system, may be used to clarify the invention. The orientation of the Cartesian coordinate system may be different, for example, such that the z-axis has a component along the horizontal plane.

With an SFG laser, the frequency of the first light beam 12 and the second light beam 14 are summed by the summing crystal 16. For instance, the first laser beam 12 (having an output at 1064 nm or 282 THz) and the second laser beam 14 (having an output of, for instance, 1562 nm or 192 THz) can be combined by the summing crystal 16 to obtain a laser beam 20 with a wavelength of 633 nm (474 THz).

Summing crystals are optical crystals, typically single crystals (monocrystalline optical materials), which are used as gain media for lasers, such as solid state lasers. Sum-frequency generation (SFG) is a second order nonlinear optical process based on the annihilation of two input photons at angular frequencies ω₁ and ω₂ while, simultaneously, one photon at frequency ω₃ is generated. This can be regarded as a second order phenomenon in nonlinear optics, and typically occurs under conditions where the light is interacting with matter, which is asymmetric (for example, surfaces and interfaces), and the input light has a very high intensity. Sum-frequency generation is a “parametric process”, meaning that the photons satisfy energy conservation, leaving the matter of the crystal unchanged.

The summing crystal may be a periodically poled lithium niobate (PPLN) crystal. The crystal may include one or more dopants, typically rare earth ions or transition metal ions. For instance, the crystal may be doped with MgO, neodymium, ytterbium, erbium, or chromium.

Please note that the optical crystal 20 may have any optical function, including but not limited to frequency doubling, difference frequency generation, sum frequency generation, optical parametric oscillation, and other nonlinear processes. As an example, embodiments of the present disclosure will be described with respect to summing, but the concept is applicable to all possible optical crystals and tuneable lasers.

A known method of stabilising the output of an SFG laser is to lock the laser frequency output to a spectral line of a gas absorption cell. To stabilize a laser to a gas dip by wavelength modulation spectroscopy, typically a wavelength modulation is applied and the laser gas transmission signal is demodulated with an odd harmonic (e.g. 1st or 3rd harmonic) of the modulation signal to generate a control signal for locking the laser frequency to the center of a spectral line.

In the method of the present disclosure it is proposed to stabilise the output of the SFG laser system 10 by ensuring stabilised inputs.

Generally referring to FIG. 2, a sum frequency generated (SFG) light source 10 may comprise a first tuneable light source L1 and a second tuneable light source L2. The first light source L1 can generate a first light beam 12. The first light beam at least includes radiation having a first frequency f₁. The second light source L2 can generate a second light beam 14. The second light beam at least includes radiation having a second frequency f₂. An outlet of the first light source L1 and an outlet of the second light source L2 are connected to an inlet of a summing crystal 16, for instance via an optical fiber. The summing crystal is adapted to receive the first light beam 12 and the second light beam 14. The crystal 16 can provide a third light beam 20, at least including radiation having a third frequency. The third frequency may be the sum of the first frequency and the second frequency.

The first light source L1 and the second light source L2 may be tuneable lasers. The first and second light source may be controlled by respective first and second amplifiers A1 and A2. The lock-in amplifiers A1 and A2 may be controlled by a controller 22. Herein, the controller may provide a setpoint or driving signal to the respective amplifiers. The amplifiers A1 and A2 provide a corresponding actuating signal, such as piezo voltage, to the respective light sources.

The first light source L1 and the second light source L2 may be provided with a first and second gas reference cell 24, 26 respectively. Each gas reference cell 24, 26 is provided with a corresponding reference light sensor 28, 30, a gas cell light sensor 32, 34, and typically a beam splitter 36, 38. Respective optical pathways receiving the output of the respective lasers L1 and L2 may be provided with first and second beam splitters 40, 42 to direct a fraction of the first and second light beams 12, 14 to the respective gas reference cells 24, 26. Said fraction may be, for instance, in the range of 0.1 to 5%, for instance about 1%, of the light received. The gas cell beam splitters 36, 38 may direct part, typically half, of the received light to the respective gas reference cells 24, 26 and the other part to the reference light sensors 28, 30.

The respective amplifiers A1 and A2 may receive the signals as recorded by the respective light sensors 28 to 34. The difference between the gas cell signal and the reference signal may enable to lock to a spectral line of the respective gas reference cell 24, 26. In response, the first amplifier A1 may, as a result, add a first offset to the input to the first light source L1. The second amplifier A2 may, to correct the light source signal if and when needed, add a second offset to the input to the second light source L2.

When referring herein to a fraction or part of the light beam, this may be meant as a measure of power. Herein, the fraction may be expressed as luminous intensity, which is a measure of the wavelength-weighted power emitted by a light source in a particular direction per unit solid angle. The latter may be based on the luminosity function, a standardized model of the sensitivity of the human eye. The SI unit of luminous intensity is the candela (cd). Alternatively, the description herein may relate to other suitable measures to indicate light power, for instance luminous energy [lm·s], luminous flux [lumen], or expressed in general units of energy [W] or [J/s].

For instance, the method may include stabilising the first laser output 12 at a first frequency or first wavelength, for instance 1064 nm. The method may include stabilising the second laser output 14 at a second frequency or second wavelength, for instance 1562 nm. The stabilized input beams 12, 14 result in a stabilised SFG output 20, for instance having a wavelength of 633 nm. It will be appreciated that the wavelength outputs provided here are merely exemplary and the methods herein may be applied to any combination of frequencies or wavelengths.

The laser frequency of one or both input lasers L1, L2 may be adjusted, to thereby also control the frequency of the summed SFG laser 20. Control of the laser may involve, for instance, adjusting a controllable parameter, for instance using thermal control, or current and/or voltage applied to a piezo actuator.

If no wavelength modulation is desired for an SFG output, it is proposed that the input lasers, i.e. first laser 10 having a first output wavelength and second laser L2 having a second output wavelength, are each locked to respective wavelength modulation signals. For example, the first laser L1 with a first laser output, for instance of 1064 nm, is locked to the spectral line of the first gas absorption cell 24 with a wavelength modulation signal s1. The second laser L2 with a second laser output, for instance of 1560 nm, is locked to the spectral line of the second gas absorption cell 26 with a wavelength modulation signal s2.

The modulation signals s1 and s2 are chosen to be 180° out-of-phase with respect to each other. Such, the modulation is cancelled in the sum-frequency:

$${f}_{l 1} + {f}_{l 2} = {f}_{out}$$

wherein the frequency of the first laser, fₗ₁=282 THz+A sin(2π·f_{mod}·t) and the frequency of the second laser, fₗ₂=192 THz−A sin(2π·f_{mod}·t). Herein, f_{mod} is the frequency of modulation. The frequency fₒᵤₜ of the SFG output 20 is given by:

$$\begin{matrix}{f}_{out} = {f}_{l 1} + {f}_{l 2} \\ = 282 THz + A sin ( 2 π \cdot {f}_{mod} \cdot t ) + 192 THz - A sin ( 2 π \cdot {f}_{mod} \cdot t ) \\ = 474 THz .\end{matrix}$$

FIG. 2 shows a schematic illustration of an exemplary arrangement for provision of such a stabilised SFG output, wherein each of first and second input lasers L1, L2 are stabilised to the respective gas reference cells 24, 26. The system 10 provides a sum-frequency laser with 180 degree out-of-phase (piezo) modulation to the two input light beams for wavelength stabilization thereof.

In operation, the SFG laser system 10 generates a sum-frequency laser 20 by summing the frequency of the first light beam 12 and the second light beam 14 of the two input lasers L1 and L2. The first laser L1 and/or the second laser L2 are stabilized to an absorption peak using the principle of wavelength modulation spectroscopy or frequency modulation spectroscopy. The wavelength modulation signals for laser L1 and laser L2 are out-of-phase and matched in amplitude, such that the sum-frequency of the SFG laser 20 is free of modulation.

When a laser is modulated around its center frequency ω_{L} at a modulation frequency ωₘ with modulation amplitude dw, the instantaneous frequency is ω=ω_{L}+dω*cos(ωₘt). The intensity of the radiation transmitted through the respective absorption cell can then be expressed as a Fourier series expansion.

Advantageously, by stabilizing the frequencies of the input lasers of the SFG laser 10 instead of locking the SFG output 20, a more time-efficient arrangement is presented as stabilization preparations may be made before measurement light is generated. Furthermore, by matching the wavelength modulation (for example by locking to a gas cell) of both input lasers, the modulation is cancelled out in the sum-frequency laser wavelength.

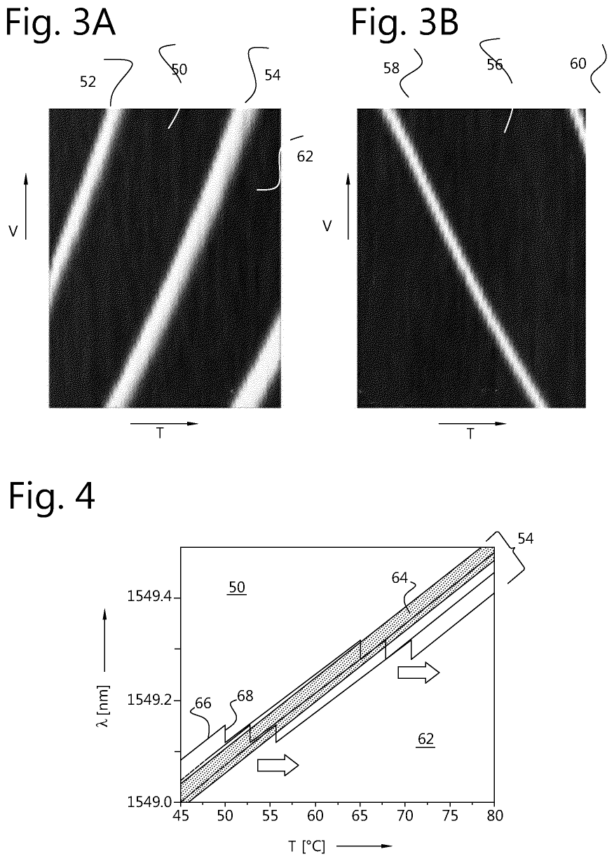

The frequency of the first lightbeam 12 and the second lightbeam 14 may be adjusted with thermal control, current and/or piezo actuators of the respective lasers L1 and L2. Existing methods involve a regular re-calibration of each light source. Recalibration herein may involve, for instance, modulating a thermal setpoint and a piezo setpoint to find a “safe zone” where no sidebands occur. See FIG. 3A for the first light source L1 and FIG. 3B for the second light source L2. Herein, the horizontal axis of the diagrams indicate temperature T of the respective resonance cavity of each laser. The vertical axis indicates the voltage V driving a piezo actuator controlling a size of the resonance cavity within a certain range of control. In FIGS. 3A and 3B, the dark areas 50, 56 indicate a ‘safe zone’, wherein the light beam produced by the respective light source comprises mostly light having a setpoint frequency, also referred to as the main mode. The bright lines 52, 54 and 58, 60 respectively indicate occurrence of side modes. A side mode typically light has one wavelength more or less than the main mode. Sidemodes can occur when standing waves occur in the resonance cavity of the having one wavelength more or less than said main mode.

Sidemodes can be detected by observing the presence of the free spectral range frequency in the optical output of the respective laser. The presence of sidemodes can be avoided by choosing an appropriate thermal and piezo setpoint.

FIG. 4 shows an example of the relation between the cavity temperature (horizontal axis) and the wavelength of the light beam. Compared to the diagrams of FIG. 3A, changing the temperature while the piezo voltage remains constant corresponds to a scanning in horizontal direction across the diagram of, for instance, FIG. 3A. Herein, with rising temperature the wavelength may initially gradually increase, for instance along line 66. However, at some point, a certain sidemode, for instance mode 54, may be activated as well. Indicated by line 68, this implies a risk that the wavelength of the main mode may jump from one wavelength to the next. This may be regarded as a ‘mode hop region’ 64, i.e. a setting wherein the laser output has a certain change of jumping or hopping to another setting. If so, first of all, the wavelength of the main mode will divert from a setpoint. And in addition, the mode hop will typically introduce a temporary jitter or inaccuracy in the output of the SFG laser output. Herein, note that the mode hop can occur in one direction but also back, thus causing multiple instants of jitter. The latter is something to be avoided in high-end applications of an SFG laser.

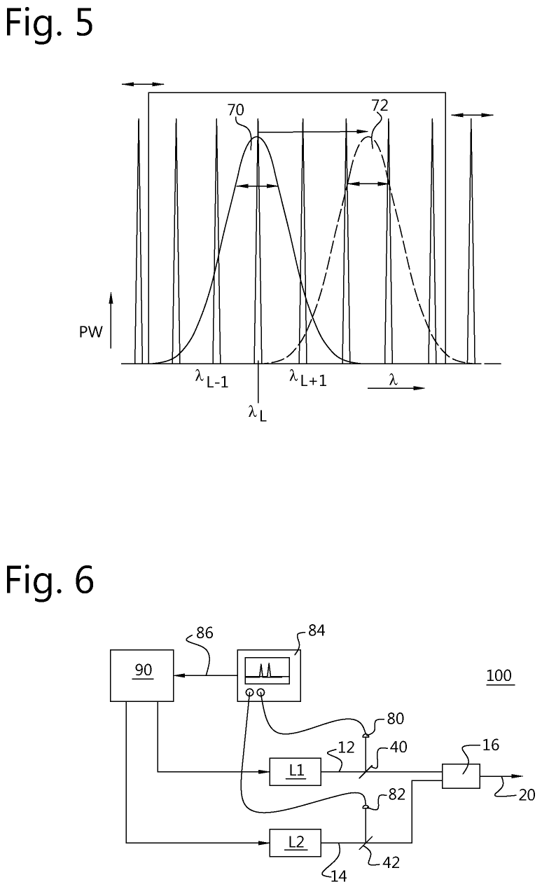

Known methods of calibrating a stabilised SFG laser to avoid sidemodes involve a regular re-calibration of thermal and piezo setpoints to find a “safe zone” where no sidebands occur, thereby providing a stable SFG output. FIG. 5 exemplifies power (vertical axis) versus wavelength (horizontal axis) of respective modes. Line 70 may exemplify a setting relating to a safe zone. Herein, the power of the main mode λ_{L} significantly exceeds the power of the two adjacent side modes, having wavelength λ_{L+1} and λ_{L-1} respectively. Line 72 exemplifies a mode hop region. Herein, the power of two adjacent modes is of a comparable order of magnitude, risking the main mode to jump or hop from one wavelength to the next, or vice versa.

The effective total cavity of input lasers L1 and/or L2 may have a length of about 4 cm and a free spectral range on the order of 2.5 GHz. When the laser temperature is changed, the mode selector and the cavity modes are tuned together and the laser wavelength changes within, for instance, about 1 GHz/K. However, due to slightly different expansion coefficients of the fibres used in respective laser, the longitudinal modes will move somewhat less than the center wavelength of the spectrally narrow grating. Eventually a situation occurs where two longitudinal modes experience substantially the same output coupler reflectivity. This is illustrated as situation in FIG. 5. This may occur, for instance, up to three times over the whole thermal tuning range.

Sidemodes can be detected by observing the presence of the free spectral range frequency in the optical output of the laser. The presence of sidemodes can be avoided by choosing an appropriate thermal and piezo setpoint.

A problem is that this calibration may only be performed with the laser amplifier off, as passing over a side band will result in a mode-hop (IFM loss of lock) and potential damage to the laser amplifier. As mentioned in the introduction, during calibration the center frequency of the SFG laser may vary. A separate calibration may result in throughput loss.

The goal is to always stay in a zone where sidebands have an amplitude below a set threshold. For instance, control each laser to stay in a zone where sidebands have an amplitude or power significantly smaller than the main mode. Significantly smaller herein, or the threshold, may be equal to or smaller than 40 dB relative to the main mode.

FIG. 6 provides an embodiment of a system 100 of the disclosure, allowing sidemode detection during operation of the SGF laser. The system 100 basically is a sum-frequency generated laser with two tuneable input lasers, L1 and L2. The first light source L1 has a first frequency f₁ and the second light source L2 has a second frequency f₂. The first light beam 12 and the second light beam 14, i.e. the optical outputs of L1 and L2 respectively, are combined in a frequency sum crystal 16. The crystal generates a light beam 20 having a third frequency f3, wherein frequency f₃ may be f₁+f₂. In a practical example, f1 is about 192 THz, and f2 is about 281 THz.

In order to detect the emergence of a sidemode of at least one of the lasers L1 and L2, the frequencies of the first and second light beams 12 and 14 of laser L1 and L2 are scanned in opposite direction, and 180° out-of-phase with each other, with matched tuning trajectories. Herein, the sum-frequency of the light beam 20 remains constant during scanning of beams 12 and 14.

At least part of the first and second light beams 12, 14 may be diverted to a light sensor 80, 82 respectively. Diverting the first and second light beams 12, 14 may involve a beam splitter 12, 14 or comparable optical element. Said at least part of the first light beam and second light beam may, in a practical embodiment, be about 0.1 to 10% of the light, for instance about 0.5 to 2%, for instance about 1%.

The sidemode detector may comprise the power sensors 80, 82. The sensors 80, 82 may be connected to a processing device 84, such as a computer or dedicated processor. The processor 84 typically is provided with an algorithm that can calculate the power of the sidemode from the sensor data. The power of the sidemode herein implied the power of the free spectral range frequency. The processor provides a signal 86 to a controller 90 for controlling the SGF light source 100.

The first light sensor 80 and the second light sensor 82 may be suitable to directly detect power of spectral frequencies in the respective light beams. The sensors 80, 82 may be, for instance, a high-frequency optical power and/or energy meter. Such sensors may be obtained from, for instance, Thorlabs Inc., Newton, NJ (US).

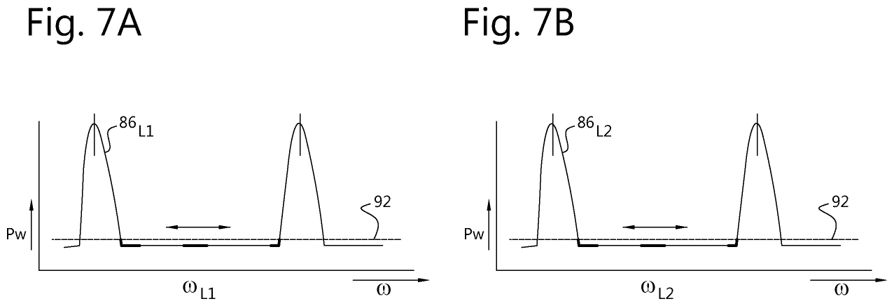

FIGS. 7A and 7B exemplify the signal 86 for light sources L1 and L2 respectively, i.e. signals 86_{L1} and 86_{L2}. The horizontal axis represents frequency (ω [Hz]) or alternatively wavelength. The vertical axis indicates power of the light at a certain frequency. Herein ω_{L1} and ω_{L2} indicate the main modes, or setpoint, for the first light source L1 and the second light source L2 respectively. At certain times, for instance periodically or continuously, the frequencies of both light sources are modulated around the main mode, in opposite direction. Once the detected power of a side mode reaches or exceeds the threshold level 92, the controller 90 will reverse the direction of the modulation for both light sources L1 and L2.

Once a sidemode is detected for one of the lasers, the direction of frequency or wavelength tuning is reversed. Thereby, the sidemode is avoided while the frequency of the sum-frequency generated light beam 20 remains approximately constant. Also, as the sidemode is avoided, the SFG laser 20 is substantially free of jitter or aberrations. In particular, the significant jitter due to mode hopping is entirely prevented, as mode hops are obviated.

Sidemode detection of L1 and L2 may thus be based on power measurement of the free spectral range frequency content of each laser.

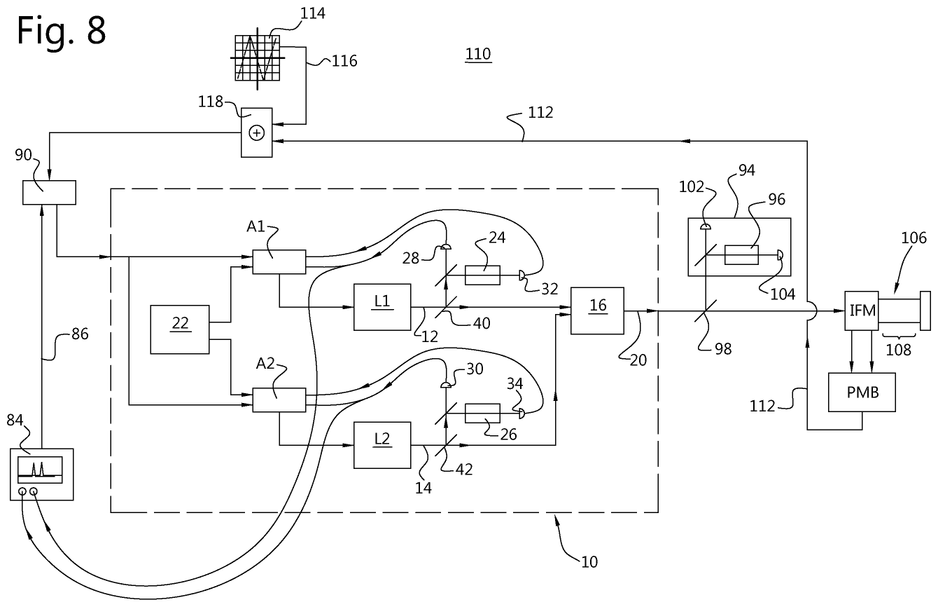

FIG. 8 shows a system 110 of the present disclosure, wherein the features of embodiments of FIG. 2 and FIG. 6 may be combined. System 110 includes a SFG light source 10, which can generate a stable SGF light beam 20. Herein, first and second light sources L1 and L2 can be stabilized, as described with respect to the embodiment shown in FIG. 2.

In the system 110, the reference sensors 28, 30 can a measurement of the spectral range. In other words, the sensors 28, 30 have a double function, one related to the gas absorption cells 24, 26 as a refence sensor and the other as spectral power meter. Herein, a measurement output of the sensors 28, 30 is provided both to amplifiers A1, A2 respectively, and to the processing device 84. The processor 84 in turn provides a signal 86 to the controller 90. Said signal includes a spectral analysis of the light beams 12, 14 respectively. The controller 90 in turn drives the respective first and second amplifiers A1 and A2. For instance, the controller 90 can instruct the amplifiers A1 and A2 to modulate the frequency of the first and second light source L1 and L2 in opposite direction, as described herein above with respect to FIG. 6.

The sum-frequency laser 20 may be used as a metrology laser for a position or displacement measuring interferometer or wavelength tracker interferometer application. Such application is useful to measure, for example, the position of the wafer table WT in the lithographic apparatus LA as exemplified in FIG. 1.

As shown in FIG. 8, the SGF light beam 20 may be provided to a beam splitter 98. The beam splitter diverts a small fraction of the light beam 20 to a molecular absorption cell system 94, comprising gas reference cell 96, a reference light sensor 102 and a gas cell light sensor 104. The molecular absorption cell system 94 may function substantially similar to the molecular absorption cell systems of gas reference cells 24, 26 and their respective light sensors.

The main portion of light beam 20 may be provided to an interferometer system 106. The interferometer system 106 may comprise one or multiple interferometers, to measure one or more static and/or moving target mirrors. An example of an interferometer system suitable for the method and system of the present disclosure are described in detail in, for instance, US2021072088.

As an example, the system 106 may comprise a stable cavity 108 as a reference axis, having a reflector at the end. If stable, the cavity 108 may allow the interferometer to function as a wavelength tracker. Alternatively, the reflector at the end of cavity 108 may be movable equipment. The system 106 may typically also include another axis of reference, receiving another (typically half) of the light of light beam 20. The system 106 typically includes an interferometer IFM connected to a phase measurement board PMB. The PMB can output a signal 112 representative of a phase difference.

The signal 112 can be provided to summing device 118. The summing device can receive other inputs and add these to the signal 112. For instance, the summing device can be connected to a setpoint trajectory generator 114, providing setpoint signal 116. The setpoint generator 114 may be used for mapping the phase of the ultra-stable cavity 108 to the absorption lines of gas absorption cell 96. An output of the summing device 118 can be provided to the controller 90. The controller in turn controls the first light source L1 and the second light source L2, typically via the first and second amplifiers A1 and A2.

In use, the setpoint trajectory generator 114 may add an offset to the setpoint of the first and second light sources L1 and L2, for instance to scan the sum-frequency generated laser beam 20 for the purpose of mapping the phase of the ultra-stable interferometer axis 108 against the pre-calibrated absorption spectrum of the molecular absorption cell 96.

After mapping the phase of the interferometer axis against the frequency reference cell, the phase signal 112 of the interferometer 106 may be used for wavelength measurement and/or wavelength control of the light beam 20.

In use, the embodiments of the disclosure allow to stabilize the first light source L1 and the second light source L2. Herein, the power detectors 28, 30 may be used for side mode detection and for power normalization of the signal that is passed through the gas reference cells 24, 26.

Herein below, various use cases of the embodiment of FIG. 8 are provided as an example.

Use case 1 involves phase locking the laser 20 to a pre-calibrated ultra-stable cavity 108 that has been calibrated against a molecular absorption cell, such as cell 96. Herein, the sum-frequency generated laser 20 is scanned (for instance, varied over a range of wavelengths between an upper and a lower threshold) to determine the relationship between the absorption spectrum of the reference cell 96 and the phase measured in the ultra-stable cavity 108, by phase measurement device PMB.

Herein, laser L1 and laser L2 are not scanned, i.e. set to provide a constant unvaried output, while allowing modulation of the sum-frequency of the SFG laser beam 20, for instance using the generator 114.

Once the phase of the ultra-stable cavity 108 is mapped against the absorption lines of gas reference cell 96, the phase of the ultra-stable cavity 108 can be used to measure and control the sum-frequency or the wavelength of the laser beam 20.

Use case 2 comprises sideband detection of seed lasers L1 and L2 of the SFG laser. Herein, the method uses opposite frequency scan directions of the respective seed lasers L1 and L2, such that the sum-frequency, i.e. the frequency of the SFG laser beam 20, remains constant.

The sum-frequency of Laser L1 and Laser L2 is kept constant by “opposite direction modulation”. This involves modulating the frequency of Laser L1 and Laser L2 in opposite directions and at the same scanning rate, to detect a sideband and avoid the sideband.

Herein, the controller 90 may provide a modulation signal to the first and second amplifiers A1 and A2. The modulation frequency, or the rate of scanning the frequency of the first and second light sources L1 and L2, may typically be chosen at sub-Hz level. The modulation signal provided by the controller 90 may have various waveforms, including but not limited to sinusoidal. Other waveforms may also be suitable. For SFG lasers in the THz region, the modulation range may typically be in the range of MHz to GHz. Modulation range herein means the frequency band or range used for modulating the frequencies of lasers L1 and L2.

The modulation of Laser L1 may be used to find the frequency where sidebands are present and/or to steer the frequency of laser L1 to a sideband-free setpoint of operation.

The modulation of Laser L2 may be used to find the frequency where sidebands are present and/or to steer the frequency of laser L2 to a sideband-free point of operation.

Use case 3 includes frequency stabilization of the SFG laser by locking the input lasers L1 and L2 to molecular absorption cells 24, 26 using opposite frequency modulation.

Herein, the summed frequency of Laser L1 and Laser L2, i.e. the frequency of SFG laser beam 20, is kept constant while modulating the frequency of Laser L1 and Laser L2 in opposite direction. Herein, the modulation frequency may typically be chosen at kHz level. The modulation range may be on the order of several MHz.

The modulation of Laser L1 may be used to determine a locking a signal to lock the laser L1 to an absorption line of the first molecular absorption cell 24. The modulation of Laser L2 may be used to determine a locking a signal to lock the laser L2 to an absorption line of the second molecular absorption cell 26.

The third use case enables to stabilize the sum-frequency of beam 20 without using the phase information signal 112 related to the interferometer 106 and its ultra-stable cavity 108.

When modulating the frequency of Laser L1 and Laser L2 in opposite direction with a certain scanning frequency, then preferably this scanning frequency should be lacking in the sum frequency of the light beam 20. Thus, the phase measurement using the ultra-stable cavity 108 will not be able to detect the modulation. If the frequency modulation is observed, then the control signals of Laser L1 and Laser L2 are not perfectly out-of-phase and small adjustments to timing and or gain may be implemented until the frequency modulation can no longer be detected by observing the phase signal 112 that is measured using the ultra-stable cavity 108.

The system of the disclosure may switch between the use cases as described above. Also, a system may be designed for one of the use cases in particular. If so, parts of the setup may be discarded if these parts are not required for the respective use. For instance, for use case 1 and/or use case 2, the gas reference cells 24 and 26 may not be required.

In the description above, reference may be made to either wavelength of a light beam or the frequency. Generally speaking, in vacuum, wavelength and frequency are related according to:

$$f = \frac{c}{λ}$$

wherein λ is wavelength, f is frequency, and c is the speed of light. Please note however that the wavelength becomes shorter if the wave of light moves from a first medium having a first density to a second, denser medium. The frequency of the light however does not change when the wave moves from one medium to another. The speed of the wave v is related to both the frequency f and the wavelength λ:

$$v = λ f$$

Combining the above expression for velocity with the definition of index of refraction, the relationship between the wavelength λ₀=c/f in vacuum and the wavelength λ₁=v₁/f in a first medium other than vacuum is:

$$\frac{λ 0}{λ 1} = \frac{\frac{c}{f}}{\frac{v 1}{f}} = \frac{fc}{fv 1} = \frac{c}{v 1} = n 1$$

wherein n₁ is the refractive index of the first medium.

When setting the tuneable lasers providing input to the SGF laser to a selected setpoint, it is an option to determine the wavelength of the laser light while travelling through the medium. An alternative is to tune the frequency of the laser light in the laser itself. Either tuning method may be suitable for the system and method of the present disclosure. For instance, wavelength tuning may be preferred for the embodiment depicted in FIG. 2. Frequency tuning may be preferred for the embodiment depicted in FIG. 6.

Although specific reference may be made in this text to the use of a lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

Where the context allows, embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1-14. (canceled)

15. A method of operating a sum-frequency laser, comprising:
simultaneously emitting a first light beam having a first frequency from a first light source and a second light beam having a second frequency from a second light source;
modulating the first frequency in a first direction and modulating the second frequency in an opposite direction and with matched tuning frequencies;
sending the first and second light beams to a summing device and outputting a stabilized sum-frequency light beam from the summing device;
detecting a sidemode in one of the first light beam and the second light beam; and
reversing the modulation direction of the first frequency and the second frequency in response to the detected sidemode exceeding a predetermined threshold.

16. The method of claim 15, wherein the threshold includes one or more of: an amplitude of the sidemode, power of the sidemode, brightness, or ratio thereof with respect to the same aspect of said first or second frequency.

17. The method of claim 15, wherein the threshold is a ratio of amplitude or power or the sidemode with respect to the power or amplitude of the first frequency or the second frequency.

18. The method of claim 15, wherein the threshold is about 40 dB, being a ratio between power of the main mode and the detected sidemode.

19. The method of claim 15, wherein the frequency change of the first light beam and the frequency change of the second light beam are 180 degrees out of phase.

20. The method of claim 15, wherein the detecting a sidemode includes power measurement of a free spectral range frequency content of the first light source and the second light source.

21. The method of claim 15, wherein the detecting a side mode includes diverting a part of the first light beam to a first sensor and diverting a part of the second light beam to a second sensor.

22. The method of claim 21, wherein the first sensor and the second sensor comprise a power detector and an algorithm for providing a signal that correlates to the power of the sidemode.

23. The method of claim 15, wherein the modulating the first frequency and the modulating the second frequency comprises thermal and/or current and/or piezo tuning of respectively the first light source and the second light source.

24. The method of claim 15, wherein the matched tuning frequencies of the modulating the first and second light beam are in a mHz to kHz range.

25. An exposure apparatus comprising:
one or more sum-frequency generated lasers using the method of operating according to claim 15.

26. A lithographic apparatus comprising:
one or more sum-frequency generated lasers using the method of operating according to claim 15.

27. A projection system for an optical lithography system comprising:
one or more sum-frequency generated lasers using the method of operating according to claim 15.
